(19) United States
(12) Patent Application Publication
(10) Pub. No.: US 2025/0239499 A1
(43) Pub. Date: Jul. 24, 2025

(54) ULTRA-THIN PACKAGED COMPONENT

(71) Applicant: PANJIT INTERNATIONAL INC., Kaohsiung City (TW)

(72) Inventors: CHUNG-HSIUNG HO, Kaohsiung City (TW); CHIEN-CHUN WANG, Tainan City (TW); CHI-HSUEH LI, Tainan City (TW); WEI-MING HUNG, Kaohsiung City (TW); JENG-SIAN WU, Taoyuan City (TW)

(21) Appl. No.: 18/764,577

(22) Filed: Jul. 5, 2024

(30) Foreign Application Priority Data
Jan. 22, 2024 (TW) 113102478

(51) Int. Cl. H01L 23/31; H01L 21/304; H01L 21/683; H01L 23/498; H01L 25/07

(52) U.S. Cl. CPC H01L 23/3135; H01L 23/3121; H01L 23/49844; H01L 21/3043; H01L 21/6836; H01L 25/072

(57) ABSTRACT

An ultra-thin packaged component and its manufacturing method are provided. The packaged component includes a die, at least one conductive component, an encapsulant layer, and multiple conductive contacts. The encapsulant layer surrounds and covers the die and the conductive component, with multiple conductive contacts placed on the surface of the encapsulant layer that electrically connect the die and the conductive component. During the manufacturing of the packaged component, the die and the conductive component are first encapsulated with the encapsulant layer and then simultaneously thinned through grinding. Such process protects the die with the encapsulant layer to prevent cracking and reduces the thickness of the base layer of the die closer to that of its epitaxy layer, achieving the objective of thinness.

### CROSS-REFERENCE TO RELATED APPLICATIONS

This application claims the priority benefit of TW application serial No. 113102478, filed on Jan. 22, 2024. The entirety of the above-mentioned patent application is hereby incorporated by reference herein and made a part of the specification.

### BACKGROUND OF THE INVENTION

### 1. Field of the Invention

The present invention relates to a packaged component, particularly to an ultra-thin packaged component.

### 2. Description of the Related Art

With reference to FIG. 3, which illustrates a conventional packaging structure. The overall thickness of the packaging structure can generally be considered as being composed of A1 to A4, where A1 represents the thickness of the lead frame 301, A2 represents the thickness of the die 302, A3 is the loop height of the wire 304, and A4 refers to the thickness of the encapsulant 305 covering the wire 304. The die 302 is attached to the lead frame 301 with silver paste 303. Due to limitations of conventional manufacturing methods in this packaging structure, the total thickness A1+A2+A3+A4 in most packaging products is at least 600 μm, which is difficult to be further reduced.

Further with reference to FIG. 4, which shows another conventional packaging structure. The difference from the earlier mentioned structure is the replacement of the original wire 304 with a conductive clip 306. This packaging structure is also subject to the limitations of conventional manufacturing methods, and its overall thickness is even greater than the structure using the wire 304 shown in FIG. 3. For most packaging products, the packaging structure shown in FIG. 4 has a thickness of at least 1 mm.

In both packaging structures in FIG. 3 and FIG. 4, a wafer is ground and cut to obtain the die 302 before proceeding with the packaging process. Since the wafer cannot be excessively thinned during the grinding process, its minimum thickness after grinding is approximately between 150 and 320 μm. Otherwise, the wafer is prone to cracking. Therefore, it is difficult to achieve the goal of thinness in packaging structures that include this die 302.

### SUMMARY OF THE INVENTION

An objective of the present invention is to provide an ultra-thin packaged component manufacturing method, thereby producing an ultra-thin packaged component with relatively uncomplicated steps.

The ultra-thin packaged component manufacturing method of the present invention includes:
temporarily attaching multiple dies and multiple conductive components to multiple packaged component positions on a carrier, wherein each die is adjacent to its corresponding conductive component;
mounting an encapsulant layer to cover each die and each conductive component, wherein a surface of each die and a surface of each conductive component are exposed and uncovered by the encapsulant layer;
mounting an insulating layer on a surface of the encapsulant layer, wherein the surfaces of each die and each conductive component are uncovered by the encapsulant layer;
mounting a conductive contact on the surfaces of each die and each conductive component;
grinding the backsides of the dies, multiple conductive components, and the insulating layer simultaneously, reducing the thickness of each die to a predetermined thickness;
mounting a patterned backside circuit on the backside of the encapsulant layer, electrically connecting the backside of each die to the backside of the corresponding conductive component, thus forming multiple packaged components; and
performing a singulation step to separate the packaged components.

With the method described above, the present invention reduces the thickness of the die in a relatively safe way, lowering the risk of cracking in the die, and reducing the overall volume of the packaged component, thereby achieving the requirement of the ultra-thin packaged component.

The ultra-thin packaged component of the present invention includes:
a die, including a base layer and an epitaxy layer, wherein the thickness of the base layer is no more than four times the thickness of the epitaxy layer;
at least one conductive component, mounted by a side of the die; a bottom surface of the at least one conductive component is electrically connected to the backside of the base layer through a backside circuit;
an encapsulant layer, surrounding and covering the side of the die and a side of the conductive component, and exposing the top surface and the bottom surface of the die and the conductive component;
multiple conductive contacts, formed on the surfaces of the die and the conductive component, and electrically contacting the die and the conductive component.

Other objectives, advantages and novel features of the invention will become more apparent from the following detailed description when taken in conjunction with the accompanying drawings.

### BRIEF DESCRIPTION OF THE DRAWINGS

FIG. 1A to FIG. 1J are schematic diagrams of a manufacture process of the ultra-thin packaged component manufacturing method of the present invention.

FIG. 2A is a sectional schematic diagram of an embodiment of the ultra-thin packaged component of the present invention.

FIG. 2B is a three-dimensional external view of an embodiment of the ultra-thin packaged component of the present invention.

FIG. 3 is a schematic diagram of a conventional package structure with wiring bonding.

FIG. 4 is a schematic diagram of a conventional package structure with clip bonding.

### DETAILED DESCRIPTION OF THE INVENTION

The present invention is an ultra-thin packaging structure suitable for discrete components, such as diodes, transistors, and thyristors, where the overall thickness of the component after packaging can be less than 150 μm or even below 100 μm. The goal of thinness is achieved without highly complex processes, and can be realized through panel-level packaging. The manufacturing process is further detailed below.

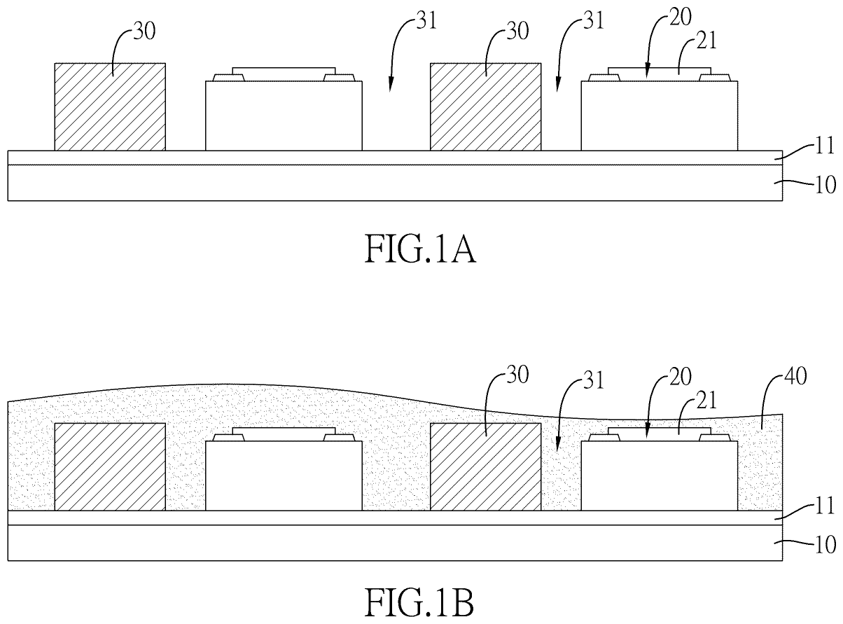

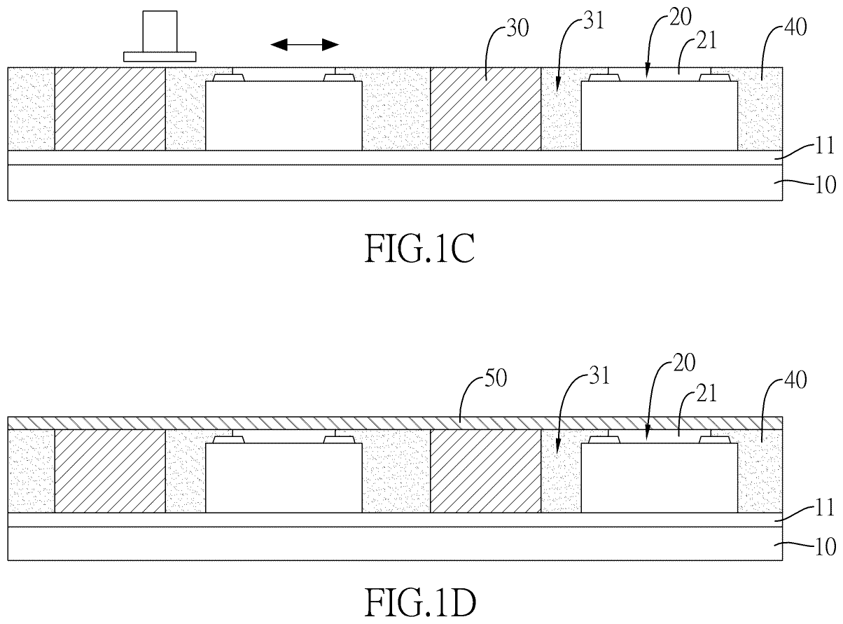

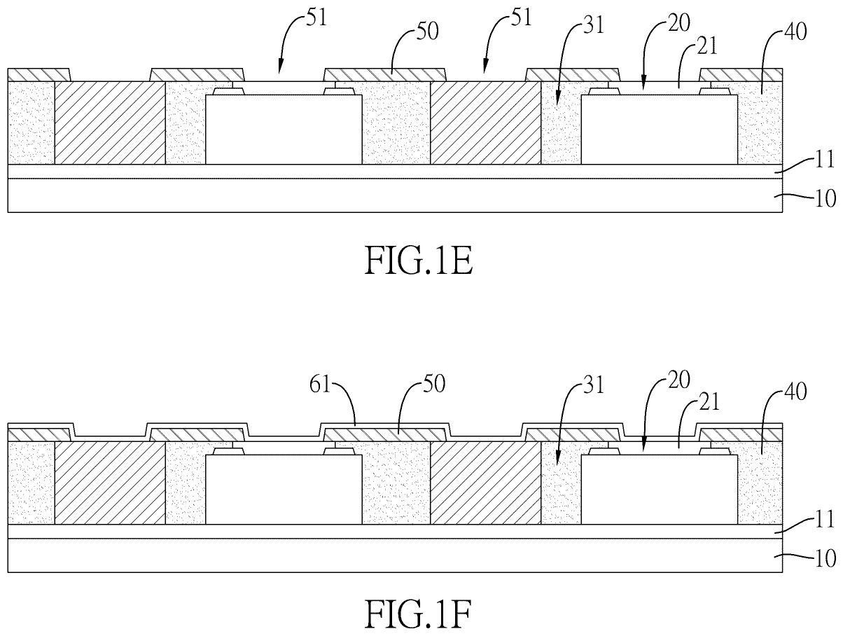

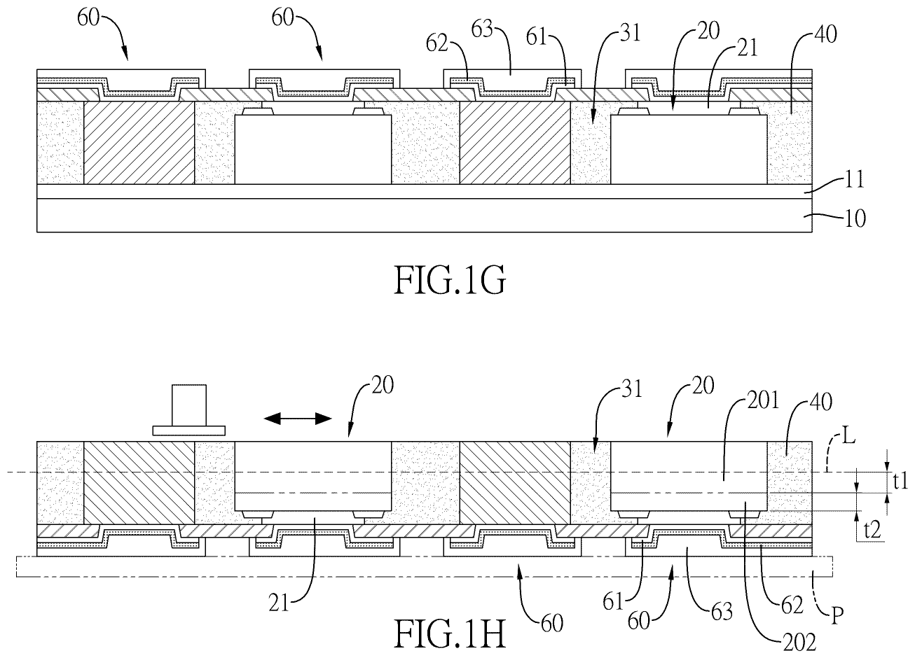

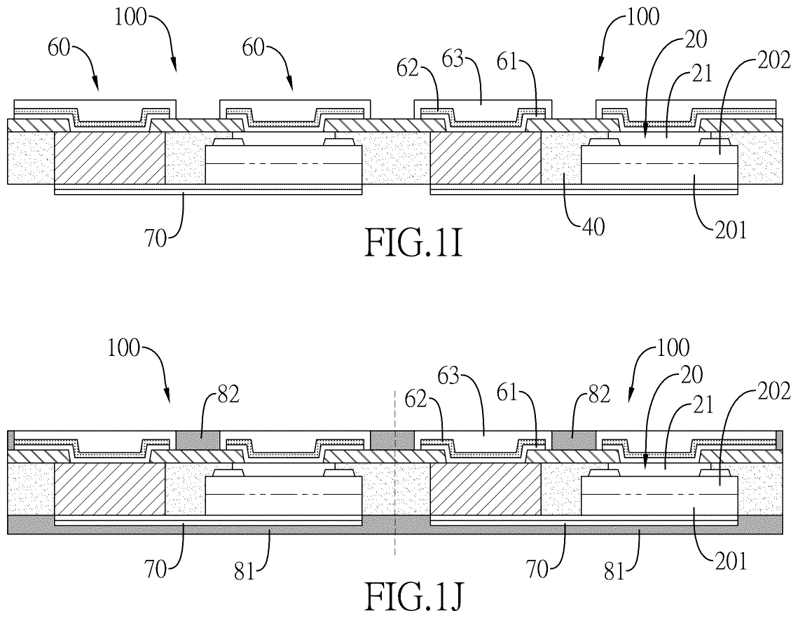

With reference to FIG. 1A, preparing a carrier 10 with a surface equipped with a double-sided tape 11. Temporarily attach multiple dies 20 and multiple conductive components 30 on the predefined packaged component positions on the tape 11. The height of each die 20 is not restricted, and can be manufactured from a wafer that has not been ground or has been ground and then cut. For example, the thickness of such wafers can range from 150 to 650 μm, and the type of the wafer may be silicon (Si) wafer, silicon carbide (SiC) wafer, sapphire (Al₂O₃) wafer, gallium nitride (GaN) wafer, glass wafer, etc., and not limited to these. In the present embodiment, a highly doped N-type silicon wafer including an epitaxy layer is taken as example. The dies 20 obtained from cutting this wafer maintain a consistent height with the wafer, and at least one signal contact 21 is formed on the top surface of each die 20. The dies 20 are extracted from the cut wafer using a picking device and then transferred and adhered to the double-sided tape 11.

Conductive components 30 are placed around or on at least one side of each die 20, with their bottom surfaces also temporarily adhered to the double-sided tape 11. In one embodiment, the conductive components 30 are formed from a metal substrate (e.g., copper substrate) with multiple through-openings 31 each respectively corresponding to the positions of the dies 20, allowing the dies 20 to be appropriately placed within the openings 31. In the embodiment, the thickness of the metal substrate is approximately equal to or slightly greater than the height of the dies 20, preventing excessive grinding and damage during subsequent grinding processes.

With reference to FIG. 1B, the encapsulation process mainly includes completely covering each die 20 and each conductive component 30 with an encapsulant layer 40 made from a dielectric material. The encapsulant layer 40 fills the openings 31 and covers the dies 20 and the conductive components 30.

With reference to FIG. 1C, which shows the process of smoothing and cleaning the surface of the encapsulant layer 40 to achieve a flat surface. In one embodiment, the surface of the encapsulant layer 40 is ground until the conductive components 30 and the dies 20 are exposed, making the encapsulant layer 40, the conductive components 30 and the dies coplanar. In another embodiment, the encapsulant layer 40 is ground to a predefined thickness to maintain coverage over the conductive components 30 and dies 20 without exposing them.

With reference to FIG. 1D, after the surface of the encapsulant layer 40 has been smoothed and the conductive components 30 and dies 20 are exposed, an insulating layer 50 is further mounted on the surfaces of the encapsulant layer 40, the conductive components 30, and dies 20. In one embodiment, an insulating layer 50 of the required thickness is laminated or pressed onto the surfaces to ensure sufficient insulation effect. If the encapsulant layer 40 retains adequate thickness after grinding, such as still covering the conductive components 30 and the dies 20, a thinner insulating layer 50 may be used, or the insulating layer 50 may be omitted.

With reference to FIG. 1E, conductive openings 51 are formed on the surface of the insulating layer 50 or the surface of the encapsulant layer 40, exposing the conductive components 30 and the dies 20 through these conductive openings 51. In the embodiment, laser is used to remove the covering material above the conductive components 30 and the dies 20, such that the signal contacts 21 of the dies 20 are exposed in the conductive openings 51. In other embodiments, other technique such as patterned etching can also be used to remove the covering material and form the conductive openings 51.

With reference to FIG. 1F to FIG. 1G, a redistribution layer (RDL) is formed, providing a conductive contact 60 in each of the conductive openings 51. As shown in FIG. 1F, at first, a seed layer 61 is formed to cover the surface of the insulating layer 50 and the inner surfaces of the conductive openings 51, such that the seed layer 61 at least contacts the surfaces of the conductive components 30 and the signal contacts 21. The seed layer 61 may be a metal layer formed by methods such as electroless plating or sputtering, for example, titanium/copper. Then, as shown in FIG. 1G, a metal layer is formed on the surface of the seed layer 61. The metal layer could be a stack of different metals or composite metal, for example, a copper layer 62 followed by a tin layer 63 formed on the seed layer 61 using pattern plating, tenting processes, etc., thus constituting a conductive contact 60 over each conductive opening 51. That is, the seed layer 61 covers a portion of the insulating layer 50, and exposes another portion of the insulating layer 50 that covers the opening 31 filled with the encapsulant layer 40, and the seed layer 61 at least covers partial surface of the conductive component 30 and the signal contact 21 of the die 20, and electrically connects the conductive component 30 and the die 20. Adjacent conductive contacts 60 are insulated from each other by the insulating layer 50 or the remaining encapsulant layer 40 to prevent short-circuiting.

With reference to FIG. 1H, the carrier 10 and the double-sided tape 11 are removed, and the thinning process is conducted. The thinning process involves simultaneously grinding the backsides of the encapsulant layer 40, the conductive components 30, and the dies 20 to achieve the desired product thickness. Since each die 20 includes a base layer 201 and an epitaxy layer 202 on top, the thinning process grinds the surface of the base layer 201, making the thickness of the base layer closer to that of the epitaxy layer 202. For instance, the dashed line in the figure represents the predetermined grinding stop line L, indicating the grinding should stop when the base layer 201 is reduced to the position shown by this dashed line. In one embodiment, the thickness of the remaining base layer 201 after grinding is denoted as t1, with the unchanged thickness of the epitaxy layer 202 denoted as t2, where the thickness t1 of the base layer 201 can be no greater than four times the thickness of the epitaxy layer t2 (i.e., t1<4*t2), or further reduced to t1<3*t2. According to the method of the present invention, the die 20 is ground while being supported and surrounded by the encapsulant layer 40, conductive components 30, etc., thereby providing excellent protection against cracking, the overall thickness of the die 20 can be significantly reduced, and the overall thickness of the base layer 201 and the epitaxy layer 202 even reach as low as 30 μm. In one embodiment, a support carrier P can be temporarily adhered to the top surface of the die 20 during grinding to enhance support and reduce the risk of damage to the die.

With reference to FIG. 1I, after completing the thinning process, a backside circuit 70 is formed on the backside of the die 20. The backside circuit 70 can be a single-layer metal or a stack of multiple-layer metal materials, or an interwoven stack forming multiple layers of redistribution (RDL) circuit layers. The patterned backside circuit 70 electrically connects the die 20 to the corresponding conductive component 30, thus forming multiple packaged components 100. In one embodiment, the backside circuit 70 is formed by electroplating metal material layers and patterning afterward.

With reference to FIG. 1J, covering the surface of the backside circuit 70 with a first protective layer 81 (solder mask), and covering the insulating layer 50 between adjacent conductive contacts 60 with a second protective layer 82. The first and second protective layers 81, 82 are insulating dielectric materials, where the first protective layer 81 covers the surface of the backside circuit 70, and the second protective layer 82 does not cover the conductive contacts 60. After the application of the first and second protective layers 81, 82, a singulation operation is performed to separate the packaged components 100 along the cutting lanes (as shown by the vertical dashed lines) between adjacent packaged components 100.

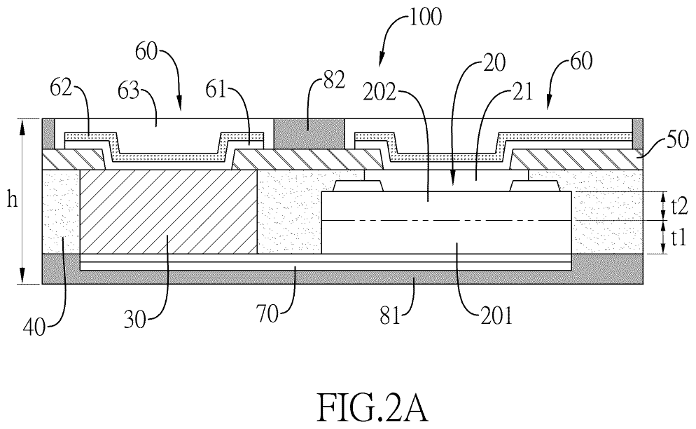

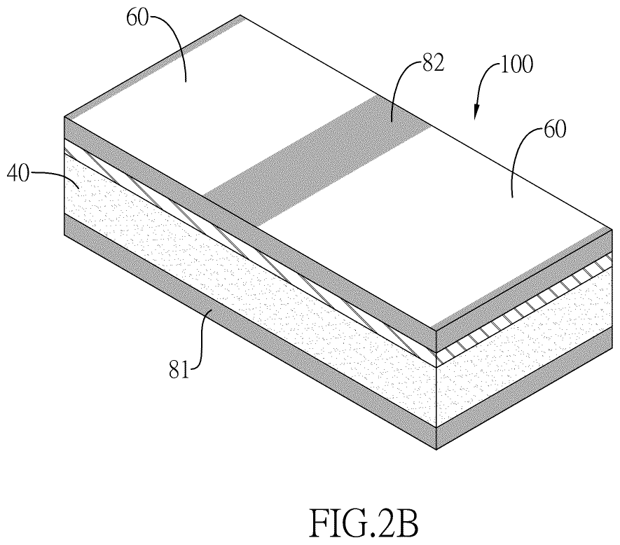

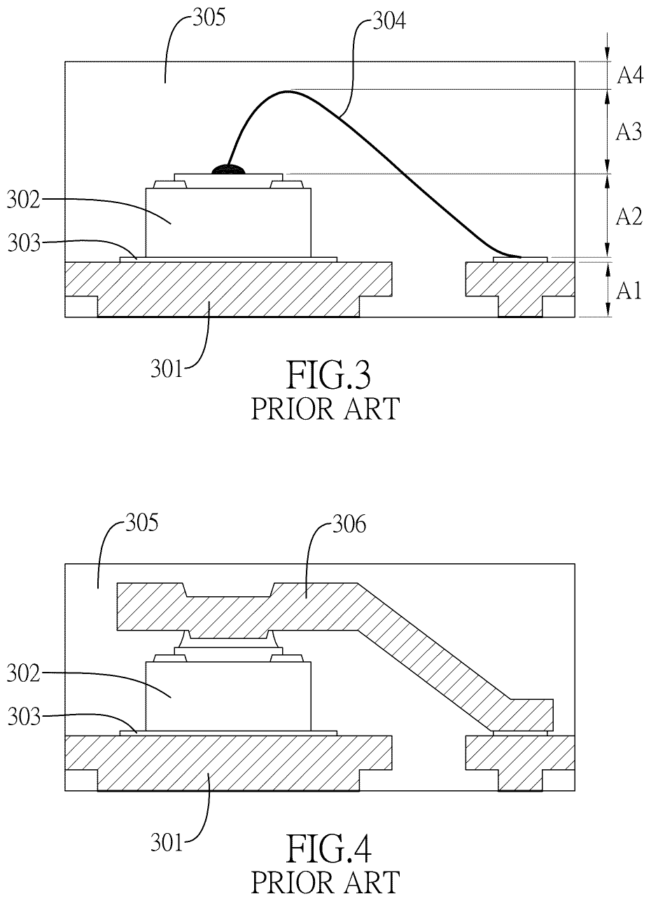

With reference to FIG. 2A and FIG. 2B, the overall component height h of the packaged component 100 completed by the aforementioned method can be less than 100 μm. The overall component height h can be considered as the relative distance between the surfaces of the first protective layer 81 and the second protective layer 82, achieving the objective of ultra-thin packaging. The packaged component 100 includes:

A die 20, including a base layer 201 and an epitaxy layer 202. After thinning through grinding, the ratio of the thickness t2 of the epitaxy layer 202 to the thickness t1 of the base layer 201 (t2:t1) can range from 1:4 to 1:3;
a conductive component 30, mounted by a side of the die 20, with the bottom surface electrically connected to the backside of the base layer 201 of the die 20 through a backside circuit 70;
an encapsulant layer 40, surrounding and covering the sides of the die 20 and the conductive component 30, exposing the top surface and the bottom surface of the die 20 and the conductive component 30;
an insulating layer 50, distributed on the surface of the encapsulant layer 40, separating the die 20 and the conductive component 30;
multiple conductive contacts 60, formed on the surfaces of the die 20 and the conductive component 30, and electrically contacting the die 20 and the conductive component 30;
a first protective layer 81 covering the bottom of the encapsulant layer 40 and the backside circuit 70;
a second protective layer 82, covering the insulating layer 50 and distributed between the conductive contacts 60, where the second protective layer 82 is coplanar with the conductive contacts 60.

According to the description above, the present invention possesses the following advantages:
1. No restriction on wafer thickness: Traditional methods require the wafer to be ground to the desired thickness before die cutting and packaging, naturally limiting die height due to the inability to grind the wafer to extremely thin levels using conventional means. However, according to the method of this invention, the dies can be cut first and then thinned during the packaging process to achieve the required thinness regardless of whether the wafer has been pre-ground.
2. Reduced risk during die pickup: Since the wafer is cut into multiple dies before being thinned, each die retains sufficient thickness, reducing the risk of damage during the die pickup and transfer process.
3. Sufficient support during die grinding: During the grinding process, the die, along with the surrounding encapsulant layer and conductive components, is thinned simultaneously rather than processing the die alone, thus the die is well-protected by the surrounding encapsulant layer and conductive components, reducing the risk of cracking.
4. Reduced internal impedance: By reducing the thickness of the base layer within the die, the internal impedance of the component itself is lowered. For MOS components, the on-resistance RDS(ON) is reduced.
5. The ultra-thin packaged components can be produced without the need for complex or specific, costly equipment.

Even though numerous characteristics and advantages of the present invention have been set forth in the foregoing description, together with details of the structure and function of the invention, the disclosure is illustrative only. Changes may be made in detail, especially in matters of shape, size, and arrangement of parts within the principles of the invention to the full extent indicated by the broad general meaning of the terms in which the appended claims are expressed.

What is claimed is:

1. An ultra-thin packaged component, comprising:
a die, having a base layer and an epitaxy layer, wherein the thickness of the base layer is no more than four times the thickness of the epitaxy layer;
at least one conductive component, mounted by a side of the die; wherein a bottom surface of the at least one conductive component is electrically connected to the backside of the base layer through a backside circuit;
an encapsulant layer, surrounding and covering the side of the die and a side of the conductive component, and exposing surfaces and backsides of the die and the conductive component;
multiple conductive contacts, formed on the surfaces of the die and the conductive component, and electrically contacting the die and the conductive component.

2. The ultra-thin packaged component as claimed in claim 1, further comprising:
an insulating layer, distributed on the surface of the encapsulant layer, insulatively separating the conductive contacts on the die and the conductive component;
a first protective layer, covering the backside of the encapsulant layer and the backside circuit; and
a second protective layer, covering the insulating layer and mounted between the conductive contacts, wherein the second protective layer is coplanar with the conductive contacts.

3. The ultra-thin packaged component as claimed in claim 1, wherein the ratio of the thickness of the epitaxy layer to the thickness of the base layer is ranged from 1:4 to 1:3.

4. The ultra-thin packaged component as claimed in claim 1, wherein the die is respectively placed within an opening formed between two of the conductive components, the thickness of the conductive component is equal to the height of the die.

5. The ultra-thin packaged component as claimed in claim 1, wherein the conductive contact is constituted with a stack of a copper layer, a tin layer and a seed layer.

6. The ultra-thin packaged component as claimed in claim 1, wherein the conductive contact is formed by using pattern plating or tenting process.

7. The ultra-thin packaged component as claimed in claim 1, wherein the conductive contact is formed by using electroless plating or sputtering.

8. The ultra-thin packaged component as claimed in claim 7, wherein the conductive contact is made of titanium or copper.

9. The ultra-thin packaged component as claimed in claim 5, wherein the seed layer covers a portion of the insulating layer, and exposes another portion of the insulating layer that covers the opening filled with the encapsulant layer.

10. The ultra-thin packaged component as claimed in claim 5, wherein the seed layer at least covers partial surface of the conductive component and a signal contact of the die, and electrically connects the conductive component and the die.

11. The ultra-thin packaged component as claimed in claim 2, wherein the first protective layer and the second protective layer are made of insulating dielectric material.

12. The ultra-thin packaged component as claimed in claim 1, wherein the overall component height of the ultra-thin packaged component is less than 100 μm.
